(19) United States
(12) Patent Application Publication
(10) Pub. No.: US 2008/0294967 A1
(43) Pub. Date: Nov. 27, 2008

(54) Incremental Redundancy Coding System

(76) Inventors: Martin Tomlinson, Totnes (GB); Cen Jung Tjhai, Playmouth (GB)

Correspondence Address: Martin Tomlinson, The Old Coach House, Tristford, Harberton, Totnes, TQ9 7RZ, GB

(21) Appl. No.: 11/751,313

(22) Filed: May 21, 2007

(51) Int. Cl. H03M 13/09

(52) U.S. Cl. 714/800; 714/E11.032

(57) ABSTRACT

In packet digital communications using a two way communications medium such as wireless each received packet is subject to noise and/or interference which causes errors in some of the received symbols. A common method known as Incremental Redundancy (IR), Hybrid Automatic Repeat Request (HARQ) for corrects these transmission errors by using error detection in conjunction with transmission of additional redundant symbols forming a sequence of forward error correcting codes. Any residual errors are detected by means of a Cyclic Redundancy Check (CRC). The CRC symbols represent transmission overhead and degrade the throughput regardless of the quality of the transmission channel. This invention is concerned with providing error detection without the need for a CRC thereby improving the throughput. In a further embodiment of the invention for those systems that employ a CRC increased reliability of detection is provided which also leads to an improvement in throughput. It is shown that by adjustment of a simple threshold value, the overall packet error rate may be traded off against throughput in a flexible manner. A method of construction of a sequence of codes from a nested block code is described and an example is provided based on a nested block code of length 128. The associated performance graphs of the invention, both using and not using a CRC, for this sequence of codes are given showing the performance improvements of the invention compared to the standard arrangement using a CRC for the same sequence of error correcting codes.

### FIELD OF THE INVENTION

The field of the invention is two way digital communication systems with particular application to wireless communication systems.

### BACKGROUND TO THE INVENTION

This invention relates to packet digital communications using a two way communications medium such as wireless where each received packet is subject to noise and/or interference causing errors in some of the received symbols. Typically Forward Error Correction (FEC) is provided using convolutional codes, turbo codes, LDPC codes, or algebraic block codes and at the receiver a forward error correction decoder is used to correct any transmission errors. Any residual errors are detected using a Cyclic Redundancy Check (CRC) which is included in each transmitted codeword. The CRC is calculated for each codeword decoded from the corresponding received symbols and if the CRC is not satisfied, then the codeword is declared to be in error. If such an error is detected, the receiver requests the transmitter by means of a Automatic Repeat Request (ARQ) either to retransmit the codeword or to transmit additional redundant symbols. Since the latter process is a hybrid form of error correction coupled with error detection feedback through the ARQ mechanism it is commonly referred to as a Hybrid Automatic Repeat Request (HARQ) system.

The two known forms of HARQ are Chase combining and Incremental Redundancy (IR). Chase combining is a simplified form of HARQ wherein the receiver simply requests retransmission of the original codeword and the received symbols corresponding to the codeword are combined together prior to detection. IR provides for a transmission of additional parity symbols extending the length of the codeword and increasing the minimum Hamming distance, dₘᵢₙ between codewords. This results in a lower error rate following decoding of the extended codeword. The average throughput of such a system is higher than a fixed code rate system which always transmits codewords of maximum length and redundancy. In HARQ systems it is a prerequisite that a reliable means be provided to detect errors in each decoded codeword. This invention is able to provide an improvement on current HARQ systems by providing a more reliable means of error detection using the CRC and also provides for an improvement in throughput by basing the error detection on the reliability of the detected codeword without the need to transmit the CRC.

### BRIEF SUMMARY OF THE DRAWINGS

FIG. 1 shows the generic signal format of HARQ systems showing the CRC symbols which are included in the initial transmitted codeword and the additional redundant symbols which are transmitted at each IR stage up to the maximum number of transmissions M.

FIG. 2 shows the overall format of the codeword symbols transmitted at each stage up to the maximum number of transmissions for each data packet for an HARQ system which does not employ a CRC.

FIG. 3 shows a generic block diagram for the increased reliability HARQ system without using a CRC.

FIG. 4 shows a generic block diagram for the increased reliability HARQ system using a CRC.

FIG. 5 shows the comparative frame error rate performance of the increased reliability HARQ system without using an 8 bit CRC for an example IR code sequence derived from a nested block code based on extended binary BCH codes of length 128.

FIG. 6 shows the comparative throughput of the increased reliability HARQ system without using the CRC for an example IR code sequence derived from a nested block code based on extended binary BCH codes of length 128.

FIG. 7 shows the comparative frame error rate performance of the increased reliability HARQ system using an 8 bit CRC for an example IR code sequence derived from a nested block code based on extended binary BCH codes of length 128.

FIG. 8 shows the comparative throughput of the increased reliability HARQ system using a CRC for an example IR code sequence derived from a nested block code based on extended binary BCH codes of length 128.

### DETAILED DESCRIPTION OF THE DRAWINGS

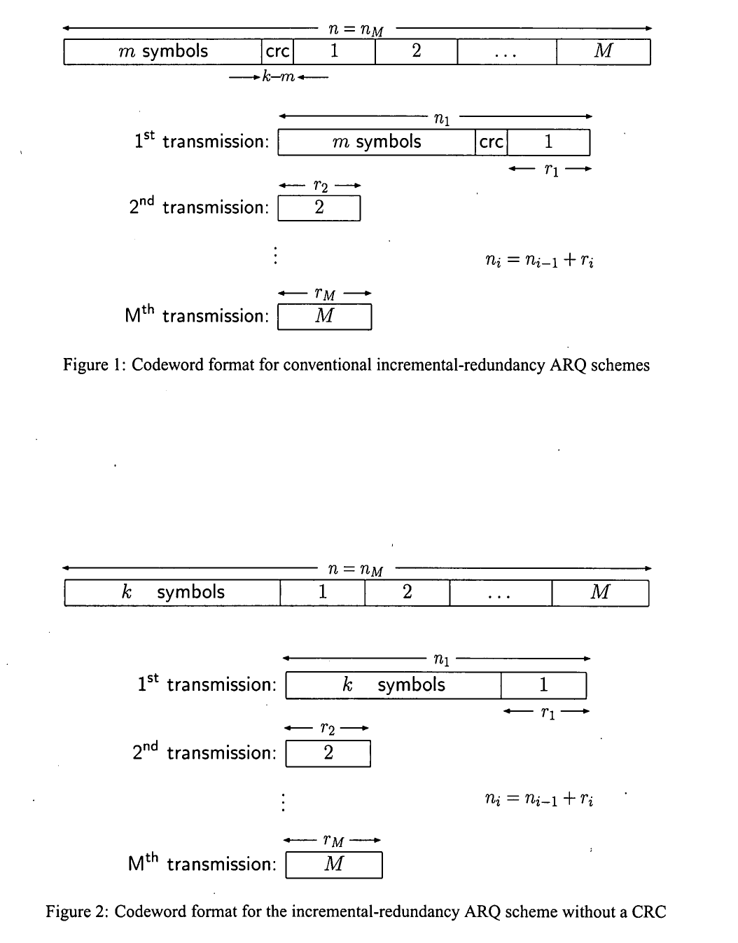

FIG. 1 shows the generic structure of the transmitted signal comprising the initial codeword followed by additional parity symbols which are transmitted following each ARQ request up to a total of M transmissions for each codeword. All of the different types of codes used in HARQ systems: convolutional codes, turbo codes, LDPC codes and algebraic codes fit into this generic codeword structure. As shown in FIG. 1 the maximum length of each codeword is n_{M} symbols transmitted in a total of M transmissions resulting from the reception of M−1 negative ACK's (NACK's). The first transmission consists of m information symbols encoded into a total of n₁ symbols. There are r₁ parity symbols in addition to the CRC symbols. This is equivalent to puncturing the maximum length codeword in the last n_{M}−n₁ symbols. If this codeword is not decoded correctly a NACK is received by the transmitter, (indicated either by the absence of an ACK being received or by a NACK signal being received), and r₂ parity symbols are transmitted as shown in FIG. 1.

The detection of an incorrect codeword is derived from the CRC in conventional HARQ systems. After the decoding of the received codeword, the CRC is recalculated and compared to the decoded CRC symbols. If there is no match then an incorrect codeword is declared and a NACK is conveyed to the transmitter. Following the second transmission the decoder has a received codeword consisting of n₁+r₂ symbols which are decoded. The CRC is recalculated and compared to the decoded CRC symbols. If there is still no match a NACK is conveyed to the transmitter and the third transmission consists of the r₃ parity symbols and the net codeword consisting of n₁+r₂+ r₃ symbols is decoded, and so on. The IR procedure ends either when an ACK is received by the transmitter or when a codeword of total length n_{M} symbols has been transmitted in a total of M transmissions.

Most conventional HARQ systems first encode the m information symbols plus CRC symbols into a codeword of length n_{M} symbols, where C_{M}=[n_{M}, k, d_{M}] denotes this code. The code C_{M} is then punctured by removing the last n_{M}−n_{M-1} symbols to produce a code C_{M-1}=[n_{M-1}, k, d_{M-1}], the code C_{M-1} is then punctured by removing the last n_{M-1}−n_{M-2} symbols to produce a code C_{M-2}, and so forth until a code C₁=[n₁, k, d₁] is obtained. In this way, a sequence of codes C₁=[n₁, k, d₁], C₂=[n₂, k, d₂], . . . , C_{M}=[n_{M}, k, d_{M}] is obtained. In the first transmission stage, a codeword C₁ is transmitted, in the second transmission stage, the punctured parity symbols of C₂ is transmitted and so on as shown in FIG. 1.

An alternative IR code construction method to produce a sequence of codes is to use a generator matrix formed from a juxtaposition of the generator matrices of a nested block code and an example is given below.

FIG. 2 shows the structure of the transmitted signal for one embodiment of this invention. The transmitted signal format is the same as FIG. 1 except that no CRC symbols are transmitted. The initial codeword consists only of the m information symbols plus the r₁ parity symbols. Additional parity symbols are transmitted following each ARQ request up to a total of M transmissions for each codeword. All of the different types of codes used in HARQ systems: convolutional codes, turbo codes, LDPC codes and algebraic codes may be used in this format including the sequence of codes based on a nested block code construction.

FIG. 3 shows one embodiment of the invention in which the k information symbols, denoted by vector u, are encoded with the Forward Error Correction (FEC) encoder into n_{M} symbols denoted as c_{M} which are stored in the Transmission Controller. In the first transmission, n₁ symbols are transmitted. At the end of the ith stage, a codeword of total length nᵢ symbols has been transmitted. This corresponds to a codeword of length n_{M} symbols punctured in the last n_{M}−nᵢ symbols. In FIG. 3, the codeword of length nᵢ is represented as a vector ν, which is then passed through the channel to produce y′ and buffered in the Received buffer as y which is Forward Error Correction (FEC) decoded in the FEC decoder which produces the most likely codeword c₁ and the next most likely codeword c₂.

In the following description the IR system is considered to have had i transmissions so that a total of nᵢ symbols have been received and the total length of the transmitted codeword is nᵢ symbols.

c₁ is denoted as

c₁=c₁₀+c₁₁x+c₁₂x²+c₁₃x³+c₁₄x⁴+ . . . +c₁₍ₙ_{ᵢ}₋₁₎xⁿ^{ᵢ}⁻¹ (1)

and c₂ is denoted as

c₂=c₂₀+c₂₁x+c₂₂x²+c₂₃x³+c₂₄x⁴+ . . . +c₂₍ₙ_{ᵢ}₋₁₎xⁿ^{ᵢ}⁻¹ (2)

and the received symbols y are denoted as

y=y₀+y₁x+y₂x²+y₃x³+y₄x⁴+ . . . +y₍ₙ_{ᵢ}₋₁₎₂xⁿ^{ᵢ}⁻¹ (3)

For each decoded codeword, c₁ and c₂, the squared Euclidean distances d²_{E}(y, c₁) and d²_{E}(y, c₂) respectively are calculated between the codewords and the received symbols y stored in the Received buffer.

d²_{E}(y, c₁) is given by

$${d}_{E}^{2} ( y , {c}_{1} ) = {\sum }_{j = 0}^{{n}_{1} - 1} {( {y}_{j} - {c}_{1 j} )}^{2} \qquad ( 4 )$$

d²_{E}(y, c₂) is given by

$${d}_{E}^{2} ( y , {c}_{2} ) = {\sum }_{j = 0}^{{n}_{i} - 1} {( {y}_{j} - {c}_{2 j} )}^{2} \qquad ( 2 )$$

The function of the Reliability estimator shown in FIG. 3 is to determine how much smaller is d²_{E}(y, c₁) compared to d²_{E}(y, c₂) in order to estimate the likelihood that the codeword c₁ is correct. The Reliability estimator calculates the squared Euclidean distances d²_{E}(y, c₁) and d²_{E}(y, c₂), and determines the difference Δ given by

Δ=d²_{E}(y,c₂)−d²_{E}(y,c₁) (6)

Δ is compared to a threshold which is calculated from the minimum Hamming distance of the first code in the sequence of codes, the absolute noise power, and a multiplicate constant termed κ. As shown in FIG. 3, Δ is compared to the Threshold by the Comparator. If Δ is not greater than the Threshold, c₁ is considered to be insufficiently reliable, and the output of the Comparator causes the ACK/NACK generator to convey a NACK to the transmitter for more parity symbols to be transmitted. If Δ is greater than or equal to the Threshold then c₁ is considered to be correct, the output of the Comparator causes the ACK/NACK generator to convey an ACK to the transmitter and in turn, the ACK/NACK generator causes the switch to close and c₁ is switched to the output û. The ACK causes the entire IR procedure to begin again with a new vector u. The way that Δ works as an indication of whether the codeword c₁ is correct or not is that if c₁ is correct then d²_{E}(y, c₁) is a summation of squared noise samples only because the signal terms cancel out. The codeword c₂ differs from c₁ in a number of symbol positions equal to at least the minimum Hamming distance of the current code, dₘᵢₙ. With the minimum squared Euclidean distance between symbols defined as d²_{S}, Δ will be greater or equal to dₘᵢₙ×d²_{S} plus a noise term dependent on the signal to noise ratio. If c₁ is not correct d²_{E}(y, c₁) and d²_{E}(y, c₂) will be similar and Δ will be small.

If more parity symbols are transmitted because Δ is less than the threshold, the dₘᵢₙ of the code increases with each increase of codeword length and provided c₁ is correct, Δ will increase accordingly.

The Reliability measure shown in FIG. 3 uses the squared Euclidean distance but it is apparent that equivalent soft decision metrics including cross correlation and log likelihood may be used to the same effect.

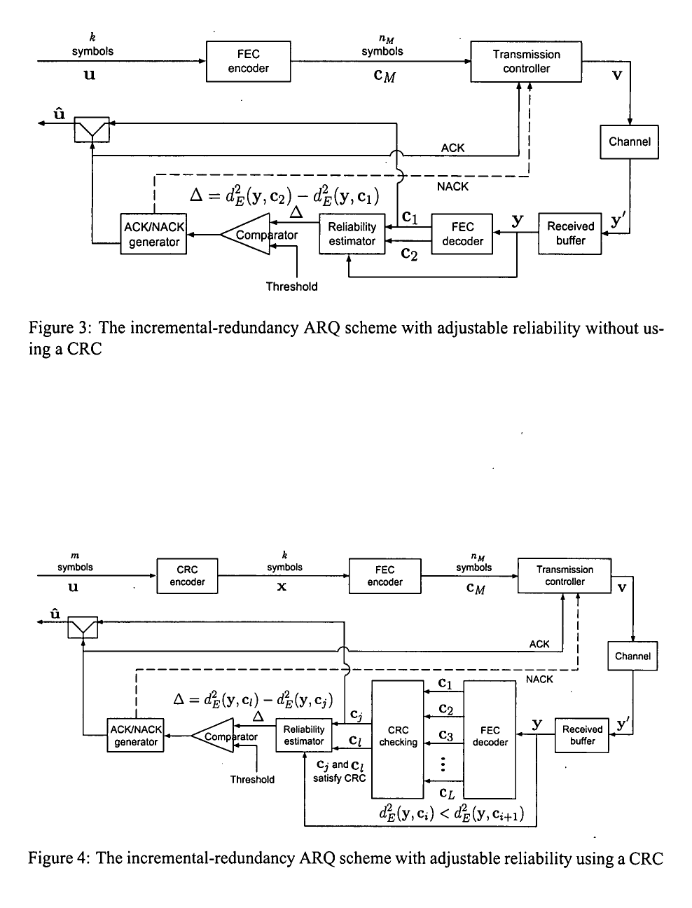

FIG. 4 shows an embodiment of the invention in which a CRC is transmitted in the first transmitted codeword. The m information symbols, shown as vector u in FIG. 4 are encoded with the CRC encoder to form a total of k symbols, shown as vector x. The k symbols are encoded by the FEC encoder into n_{M} symbols denoted as CM which are stored in the Transmission Controller. In the first transmission n₁ symbols are transmitted. At the end of the ith stage, a codeword of total length nᵢ symbols has been transmitted. This corresponds to a codeword of length n_{M} symbols punctured in the last n_{M}−nᵢ symbols. In FIG. 4, the codeword of length nᵢ is represented as a vector ν, which is then passed through the channel to produce y′ and buffered in the Received buffer as y which is Forward Error Correction (FEC) decoded in the FEC decoder. The FEC decoder produces L codewords with decreasing reliability as measured by the squared Euclidean distance between each codeword and the received symbols or as measured by an equivalent soft decision metric such as cross correlation between each codeword and the received symbols. The L codewords are input to CRC checking which determines the most reliable codeword, cⱼ, which satisfies the CRC and the next most reliable codeword, cₗ, which satisfies the CRC. The Reliability estimator shown in FIG. 4 determines the difference, Δ, of the squared Euclidean distances between codewords cⱼ and cₗ and the corresponding received symbols.

Δ is given by

Δ=d²_{E}(y,cₗ)−d²_{E}(y,cⱼ) (7)

Δ is compared to a threshold which is calculated from the minimum Hamming distance of the first code in the sequence of codes, the absolute noise power, and a multiplicative constant termed κ. As shown in FIG. 4, Δ is compared to the Threshold by the Comparator. If Δ is not greater than the Threshold, cⱼ is considered to be insufficiently reliable, and the output of the Comparator causes the ACK/NACK generator to convey a NACK to the transmitter for more parity symbols to be transmitted. If Δ is greater than or equal to the Threshold then cⱼ is considered to be correct, the output of the Comparator causes the ACK/NACK generator to convey an ACK to the transmitter and in turn, the ACK/NACK generator causes the switch to close and cⱼ is switched to the output û. The ACK causes the entire IR procedure to begin again with a new vector u.

The Reliability measure shown in FIG. 4 uses the squared Euclidean distance but it is apparent that equivalent soft decision metrics including cross correlation and log likelihood ratios may be used to the same effect.

### Code Generation Using Nested Block Codes

If C is a cyclic code, there exists a generator polynomial g(x)εF₂[x] and a check polynomial h(x)εF₂[x] such that g(x)h(x)=xⁿ^{₁}−1. Two cyclic codes, C₁ with g₁(x) as the generator polynomial and C₂ with g₂(x) as the generator polynomial, are said to be chained or nested, if g₁(x)|g₂(x), and we denote them by C₁⊃C₂. With reference to this definition, it is clear that narrow-sense BCH codes of the same length form a chain of cyclic codes. Given a chain of two codes, using a code construction method known as Construction X, a construction method first described by Sloane, N. J., Reddy, S. M. and Chen, C. L. (1972), “New binary codes”, IEEE Trans. Inform. Theory, vol. IT-18, 503-510. the code with larger dimension can be lengthened to produce a code with increased length and minimum distance.

A generalised form of Construction X involves more than two codes. Let Bᵢ be an [n₁, kᵢ, dᵢ] code, given a chain of M codes, B₁⊃B₂⊃ . . . ⊃B_{M}, and a set of auxiliary codes Aᵢ=[n′₁, k′₁, d′ᵢ], for 1≦i≦M−1, where k′ᵢ=k₁−kᵢ, a code

$${C}_{X} = [ {n}_{1} + {\sum }_{i = 1}^{M - 1} {n}_{i}^{′} , {k}_{1} , d ]$$

code can be constructed, where

$$d = min \{ \begin{matrix}{d}_{M} , {d}_{M - 1} + {d}_{M - 1}^{′} , {d}_{M - 2} + {d}_{M - 2}^{′} + \\ {d}_{M - 1}^{′} , … , {d}_{1} + {\sum }_{i = 1}^{M - 1} {d}_{i}^{′}\end{matrix} \} .$$

Denoting z as a vector of length n₁ formed by the first n₁ coordinates of a codeword of C_{X}. A codeword of C_{X} is a juxtaposition of codewords of Bᵢ and Aᵢ, where

$$\begin{matrix}( {b}_{M} & \vert 0 \vert 0 \vert & … & \vert 0 \vert 0 ) & if z ∈ {B}_{M} , \\ ( {b}_{M - 1} & \vert 0 \vert 0 \vert & … & \vert 0 \vert {a}_{M - 1} ) & if z ∈ {B}_{M - 1} , \\ ( {b}_{M - 2} & \vert 0 \vert 0 \vert & … & \vert {a}_{M - 2} \vert {a}_{M - 1} ) & if z ∈ {B}_{M - 2} , \\ & & ⋮ & & ⋮ \\ ( {b}_{2} & \vert 0 \vert {a}_{2} \vert & … & \vert {a}_{M - 2} \vert {a}_{M - 1} ) & if z ∈ {B}_{2} , \\ ( {b}_{1} & \vert {a}_{1} \vert {a}_{2} \vert & … & \vert {a}_{M - 2} \vert {a}_{M - 1} ) & if z ∈ {B}_{1} ,\end{matrix}$$

Where bᵢεBᵢ and aᵢεAᵢ.

### Example of Code Generation Using Nested Block Codes

There exists a chain of extended BCH codes of length 128 bits,
B₁=[128, 113, 6]⊃B₂=[128, 92, 12]⊃B₃=[128, 78, 16]⊃B₄=[128, 71, 20].
   Applying Construction X to [128, 113, 6]⊃[128, 92, 12] with an [32, 21, 6] extended BCH code as auxiliary code, a [160, 113, 12] code is obtained, giving
[160, 113, 12]⊃[160, 92, 12]⊃[160, 78, 16]⊃[160, 71, 20].
   Using a [42, 35, 4] shortened extended Hamming code as the auxiliary code in applying Construction X to [160, 113, 12]⊃[160, 78, 16], giving
[202, 113, 16]⊃[202, 92, 16]⊃[202, 78, 16]⊃[202, 71, 20].
   Finally, applying Construction X to [202, 113, 16]⊃[202, 71, 20] with the shortened extended Hamming code [49, 42, 4] as the auxiliary code, giving
[251, 113, 20]⊃[251, 92, 20]⊃[251, 78, 20]⊃[251, 71, 20].
   The resulting sequence of codes which are used as an example in the invention are [128, 113, 6], [160, 113, 12], [202, 113, 16] and [251, 113, 20].

The generator matrix of the last code, the [251, 113, 20] code is given by

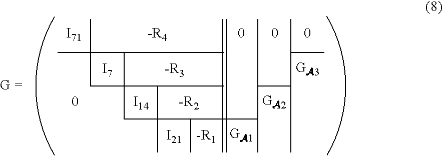

On the left hand side of the double bar, the generator matrix of the code B₁ is decomposed along the chain B₁⊃B₂⊃B₃⊃B₄. The matrices G_{A}_{ᵢ}, for 1≦i≦3 are the generator matrices of the auxiliary codes Aᵢ.

This generator matrix may be used to generate each entire codeword of length n_{M}=251 bits. The first 128 bits of each entire codeword are selected to form the codeword of the code [128, 113, 6] and are transmitted first, bit 0 through to bit 127. The next transmission (if requested by the IR system) consists of 32 parity bits. These are bit 128 through to bit 159 of the entire codeword. These 32 parity bits plus the original 128 bits form a codeword of the [160, 113, 12] code. The next transmission (if requested by the IR system) consists of 42 parity bits. These are bit 160 through to bit 201 of the entire codeword. These 42 parity bits plus the previously transmitted 160 bits form a codeword from the [202, 113, 16] code. The last transmission (if requested by the IR system) consists of 49 parity bits. These are the last 49 bits, bit 202 through to bit 250, of the entire codeword. These 49 parity bits plus the previously transmitted 202 bits form a codeword from the [251, 113, 20] code. The sequence of increasing length codewords with each transmission (if requested by the IR system) has a minimum Hamming distance which increases from 6, to 12, then to 16 and finally to 20. In turn this will produce an increasing reliability given by equation (6) or equation (7) depending on the embodiment of the invention.

### List Decoder for Turbo and LDPC Codes

The invention needs a decoder that provides several codewords at its output in order that the difference between the squared Euclidean distances (or an equivalent soft decision metric) of the most likely transmitted codeword and the next most likely transmitted codeword may be determined and compared to the Threshold. For turbo codes the conventional decoder is not a list decoder but Narayanan and Stuber in “List decoding of turbo codes”, IEEE Trans. Communications, vol 46, no 6, pp. 754-762, June 1998 show how a list decoder may be provided for turbo codes. Similarly for LDPC codes, Kristensen in his Masters thesis “List Decoding of LDPC Codes”, 2007-02, Technical University of Denmark shows how a list decoder may be provided for LDPC codes.

### Performance Results Using the Example Code Sequence Generated Using Nested Block Codes

Computer simulations of the CRC and CRC-less embodiments using the example code sequence have been carried out using an ordered reliability decoder. This decoder is well known to practitioners of the art, for example see Fossorier, M. and Lin, S., “Soft-decision decoding of linear block codes based on ordered statistics”, IEEE Trans. Inform. Theory, vol. 41, no. 5, pp. 1379-1396, 1995. The ordered reliability decoder is a list decoder with hard and soft decision outputs and for the example sequence of codes, it exhibits almost optimum performance using a list of 10⁶ codewords. For the CRC cases, an 8 bit CRC polynomial (1+x)(1+x²+x⁵+x⁶+x⁷) was used. In the simulations an ACK is transmitted if Δ is greater than Threshold or there have been M IR transmissions, otherwise a NACK is transmitted.

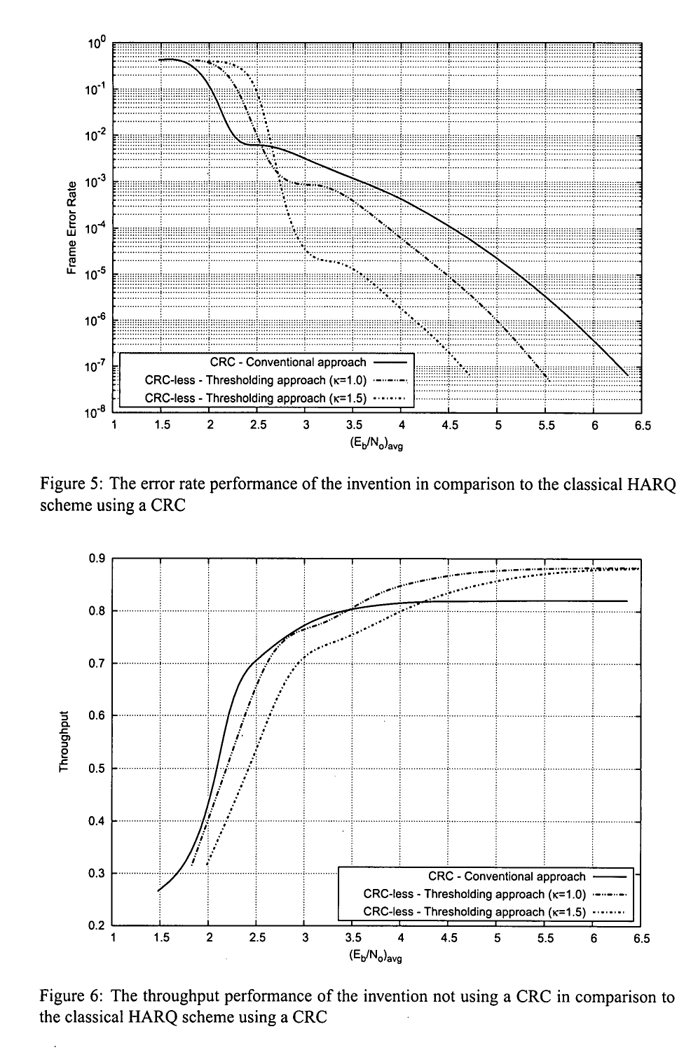

FIGS. 5 and 6 show the comparative Frame Error Rate (FER) performance and the throughput. The traditional CRC approach shows good throughput, but exhibits an early error-floor of the FER, which is caused by undetected error events. The performance of the invention shows the benefit of having increased reliability of error detection compared to the traditional CRC approach. Two Threshold settings are provided using the multiplicative constant κ and are shown in FIGS. 5 and 6 demonstrating how the Threshold setting may be used to trade-off throughput against reduced FER which is one of the benefits of the invention. The improvements in both throughput and FER provided by the invention compared to the conventional CRC approach are evident from FIGS. 5 and 6.

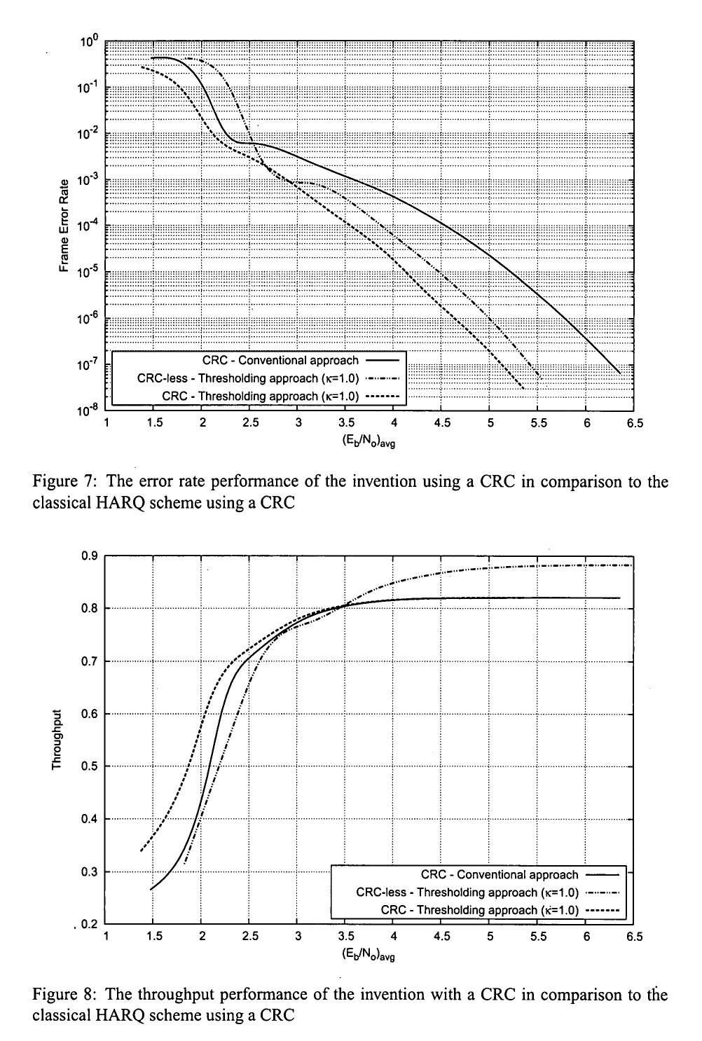

The comparative FER performance and throughput using the embodiment of the invention with a CRC compared to not using the CRC is shown in FIGS. 7 and 8. The embodiment of the invention using a CRC shows an improvement in FER, FIG. 7, over the entire range of average

$$\frac{{E}_{b}}{{N}_{o}}$$

and an improvement in throughput, FIG. 8, also over the entire range of average

$$\frac{{E}_{b}}{{N}_{o}}$$

compared to the traditional HARQ approach using a CRC.

Although the invention has been described and illustrated in the above description and drawings, it is understood that this description is by way of example only and that numerous changes and modifications can be made by those skilled in the art without departing from the broad scope of the invention. The applicants' invention should be limited only by the claims.

What is claimed is:

1. A system in which following transmission of a signal containing parity symbols additional parity symbols are requested to be transmitted based on the difference between the squared Euclidean distance of the most likely transmitted codeword including parity check symbols and the received signal and the squared Euclidean distance of the next most likely transmitted codeword including parity check symbols and the received signal.

2. A system in which following transmission of a signal containing parity symbols additional parity symbols are requested to be transmitted based on the difference between the cross correlation or other equivalent soft decision metric of the most likely transmitted codeword including parity check symbols and the received signal and the cross correlation or other equivalent soft decision metric of the next most likely transmitted codeword including parity check symbols and the received signal.

3. A system in which following transmission of a signal containing a Cyclic Redundancy Check (CRC) symbols and parity symbols additional parity symbols are requested to be transmitted based on the difference between the squared Euclidean distance of the most likely transmitted codeword satisfying the CRC, and the received signal, and the squared Euclidean distance of the next most likely transmitted codeword satisfying the CRC, and the received signal.

4. A system in which following transmission of a signal containing a Cyclic Redundancy Check (CRC) symbols and parity symbols additional parity symbols are requested to be transmitted based on the difference between the cross correlation or other equivalent soft decision metric of the most likely transmitted codeword satisfying the CRC and the received signal and the cross correlation or other equivalent soft decision metric of the next most likely transmitted codeword satisfying the CRC and the received signal.

5. A system according to claim 1 or claim 2 or claim 3 or claim 4 in which a sequence of error correcting codes having increasing minimum Hamming distance with increasing codeword length is constructed from a nested block code and used in conjunction with a list decoder.

6. A system according to claim 1 or claim 2 or claim 3 or claim 4 in which a convolutional code with punctured parity symbols is used in conjunction with a list decoder.

7. A system according to claim 1 or claim 2 or claim 3 or claim 4 in which a turbo code with punctured parity symbols is used in conjunction with a list decoder.

8. A system according to claim 1 or claim 2 or claim 3 or claim 4 in which an Low Density Parity Check (LDPC) turbo code with punctured parity symbols is used in conjunction with a list decoder.
